(19) United States
(12) Patent Application Publication
(10) Pub. No.: US 2016/0078911 A1
(43) Pub. Date: Mar. 17, 2016

(54) SEMICONDUCTOR MEMORY DEVICE HAVING COUNT VALUE CONTROL CIRCUIT

(71) Applicant: Micron Technology, Inc., Boise, ID (US)

(72) Inventors: Takayuki Fujiwara, Tokyo (JP); Kanji Oishi, Tokyo (JP); Shin Ishikawa, Tokyo (JP)

(21) Appl. No.: 14/536,499

(22) Filed: Nov. 7, 2014

(30) Foreign Application Priority Data
Nov. 8, 2013 (JP) 2013-231671

(51) Int. Cl. G11C 7/22; G11C 11/418; G11C 11/408; G11C 11/4096; G11C 11/419; G11C 11/406

(52) U.S. Cl. CPC G11C 7/22; G11C 11/419; G11C 11/406; G11C 11/408; G11C 11/4096; G11C 11/418

(57) ABSTRACT

A device includes a data storing cell array including a plurality of groups of data storing cells each configured to be accessed responsive to the input of the corresponding one of the row addresses and a count value control circuit coupled to each of the groups of the data storing cells. The count value control circuit is configured to update a count value stored in each of the groups of data storing cells by a first value responsive to the input of the corresponding one of the row addresses in a first operation mode and to set the count value stored in each of the groups of the data storing cells to a second value responsive to the input of the corresponding one of the row addresses in a second operation mode.

This application is based upon and claims the benefit of priority from Japanese patent application No. 2013-231671 filed on Nov. 8, 2013, the disclosure of which are incorporated herein in its entirely by reference.

### BACKGROUND

1. Field of the Invention

This invention relates to a semiconductor device, in particular, a semiconductor device that includes a data storing cell array including a plurality groups of data storing cells each configured to be accessed in response to the input of the corresponding one of the row addresses.

2. Description of the Related Art

Since a DRAM (Dynamic Random Access Memory), which is a typical semiconductor memory device, stores information with electric charges accumulated in a cell capacitor, the information is lost unless a refresh operation is regularly performed. Therefore, from a control device which controls a DRAM, a refresh command for making an instruction for a refresh operation is regularly issued, as described in Japanese Patent Application Laid-open No. 2011-258259. The refresh command is issued from the control device at a frequency to refresh all word lines once in a period of one refresh cycle (for example, 64 msec).

A semiconductor memory device, on which a refresh operation needs to be performed, is described in the Japanese Patent Application referenced above.

However data storing abilities of memory cells may decline depending on access histories to memory cells. And if the data storing ability of one of the memory cells declines less than an expected ability, the data stored in the memory cell might be lost regardless of performing the refresh operation.

Therefore, measures against this information loss risk are thought to be desirable. It may also be desirable to efficiently perform an additional operation test due to these new measures.

### SUMMARY

In one embodiment, there is provided a semiconductor device that includes: a memory cell array including a plurality of memory cells each configured to be accessed responsive to an input of a corresponding one of row addresses; a data storing cell array includes a plurality groups of data storing cells each configured to be accessed responsive to the input of the corresponding one of the row addresses; and a count value control circuit coupled to each of the groups of the data storing cells, the count value control circuit being configured to update a count value stored in each of the groups of data storing cells by a first value responsive to the input of the corresponding one of the row addresses in a first operation mode and to set the count value stored in each of the groups of the data storing cells to a second value responsive to the input of the corresponding one of the row addresses in a second operation mode.

In another embodiment, there is provided a semiconductor device that includes: a plurality of data storing cells configured to store a first count value; and a count value control circuit including a register circuit configured to update the first count value to the second count value responsive to a first control signal and the count value control circuit further including a write circuit coupled between the data storing cells and the register circuit. The write circuit is configured to write the second count value to the data storing cells responsive to a second control signal and to write a third count value different from each of the first and second count values responsive to a third control signal.

In still another embodiment, there is provided a semiconductor device that includes: a memory cell array including a plurality of memory cells that are arranged in a matrix including a plurality of rows and columns, each of the rows being assigned to an individual address of row addresses; an access circuit configured to access each of the rows responsive to an associated individual address of the row addresses; and a plurality of counting circuits each provided for an associated one of the rows, each of the counting circuits being configured to count a number of accesses that are performed on an associated one of the rows by the access circuit, each of the counting circuits being further configured to be loaded with a first value that is free from the number of accesses.

According to various embodiments of the present invention, an additional refresh can be performed on a memory cell with degraded information retaining characteristics, and an operation test for checking whether the additional refresh effectively functions can be efficiently performed.

### BRIEF DESCRIPTION OF THE DRAWINGS

FIG. 1 is a block diagram depicting an entire structure of a semiconductor device according to an embodiment of the present invention.

FIG. 2 is a circuit diagram depicting part of a memory cell array in an enlarged manner.

FIG. 3 is a sectional view of two memory cells sharing a bit line, each having a trench-gate-type cell transistor with a word line buried in a semiconductor substrate.

FIG. 4 is a circuit diagram of a refresh control circuit according to a first embodiment.

FIG. 5(a) is a circuit diagram of an address pointer, and FIG. 5(b) is a schematic diagram for describing a function of the address pointer.

FIG. 6 is a timing diagram for describing an operation of a semiconductor device using the refresh control circuit according to the first embodiment.

FIG. 7 is a schematic plan view depicting the structure of a memory cell array in a second embodiment.

FIG. 8 is a circuit diagram of a refresh control circuit according to an embodiment.

FIG. 9 is a block diagram of an access count portion.

FIG. 10 is a circuit diagram of a command control circuit.

FIG. 11 is a timing diagram for describing an operation of the command control circuit when an active command ACT is issued from outside.

FIG. 12 is a timing diagram for describing an operation of the command control circuit when a refresh command REF is issued from outside.

FIG. 13 is a block diagram of an address generation portion.

FIG. 14 is a timing diagram for describing an operation of an additional refresh counter and a select signal generation circuit.

FIG. 15 is a circuit diagram of the select signal generation circuit.

FIG. 16 is a timing diagram for describing an operation of a semiconductor device using a refresh control circuit according to the second embodiment.

FIG. 17 is a circuit diagram of an access count portion according to an embodiment.

FIG. 18 is a circuit diagram of an access count portion according to an embodiment.

FIG. 19 is a circuit diagram of a data storing cell array in the access count portion.

FIG. 20 is a circuit diagram of one cell included in the data storing cell array.

FIG. 21 is a timing diagram for describing an operation of the command control circuit when a test active command TACT is issued from outside.

### DETAILED DESCRIPTION OF THE EMBODIMENTS

Various embodiments of the present invention are described in detail below with reference to the attached drawings.

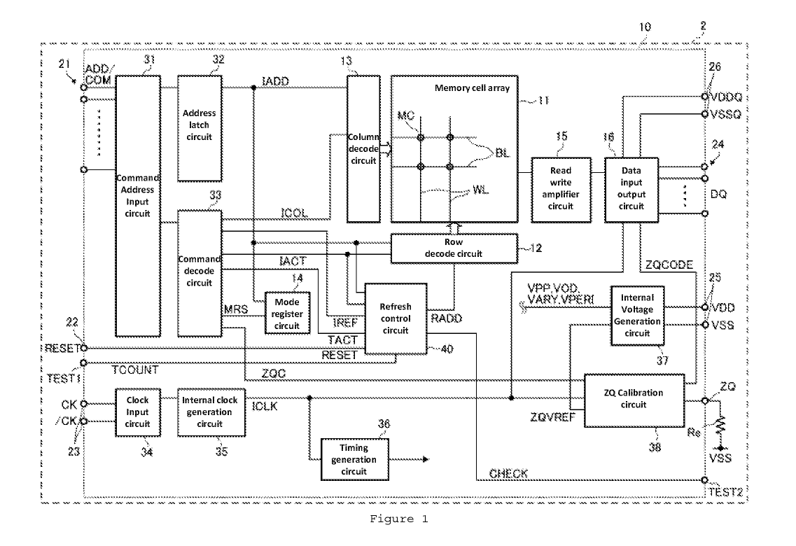

FIG. 1 is a block diagram depicting an entire structure of a semiconductor device 10 according to an embodiment of the present invention.

The semiconductor device 10 according to the present embodiment is a DDR3 (Double Data Rate 3)-type DRAM integrated in a single semiconductor chip, and is mounted on an external substrate 2. The external substrate is a memory module substrate or motherboard, and is provided with an external resistor Re. The external resistor Re is connected to a calibration terminal ZQ of the semiconductor device 10, and has an impedance for use as a reference impedance of a calibration circuit 38. In the present embodiment, a ground potential VSS is supplied to the external resistor Re.

As depicted in FIG. 1, the semiconductor device 10 has a memory cell array 11. The memory cell array 11 is configured to include a plurality of word lines WL (also referred to as rows) and a plurality of bit lines BL (also referred to as columns) and to have memory cells MC arranged at points of intersection of these lines. A word line WL is selected by a row decoder 12, and a bit line BL is selected by a column decoder 13. Here, the plurality of word lines are selected with respective unique row addresses, and are controlled by an access circuit including a command address input circuit 31, an address latch circuit 32, a command decode circuit 33, a row decode circuit 12. Specifically, a row address received by the command address input circuit 31 is supplied via the address latch circuit 32 to the row decode circuit 12 and a refresh control circuit 40. Furthermore, the row decode circuit 12 selects a word line WL based on the row address.

Also, the semiconductor device 10 is provided with command address terminals 21, a reset terminal 22, clock terminals 23, data terminals 24, power supply terminals 25 and 26, and the calibration terminal ZQ as external terminals.

Furthermore, the semiconductor device 10 may be provided with a test input terminal TEST1 and a test output terminal TEST2.

The command address terminals 21 are terminals to which address signals ADD and command signals COM are inputted from outside. The address signals ADD inputted to the command address terminals 21 are supplied via the command address input circuit to the address latch circuit 32, where the address signals ADD are latched. An address signal IADD latched by the address latch circuit 32 is supplied to the row decoder 12, the column decoder 13, or a mode register 14. The mode register 14 is a circuit where parameters indicating an operation mode of the semiconductor device 10 are set.

The command signals COM inputted to the command address terminals 21 are supplied via the command address input circuit 31 to the command decode circuit 33. The command decode circuit 33 is a circuit which generates various internal commands by decoding the command signals COM. Examples of the internal commands include an active signal IACT, a test active signal TACT, a column signal ICOL, a refresh signal IREF, a mode register set signal MRS, and a calibration signal ZQC.

The active signal IACT is a signal to be activated when the command signal COM indicates row access (active command). When the active signal IACT is activated, the address signal IADD latched by the address latch circuit 32 is supplied to the row decoder 12. With this, the word line WL specified by the relevant address signal IADD is selected.

The column signal ICOL is a signal to be activated when the command signal COM indicates column access (read command or write command). When the internal column signal ICOL is activated, the address signal IADD latched by the address latch circuit 32 is supplied to the column decoder 13. With this, the bit line BL specified by the relevant address signal IADD is selected.

Therefore, after an active command is inputted with a row address and a read command is inputted with a column address, read data is read from a memory cell MC specified by these row and column addresses. Read data DQ is outputted from the data terminal 24 to outside via a read write amplifier 15 and an input output circuit 16.

On the other hand, after an active command is inputted with a row address and a write command is inputted with a column address and write data DQ, the write data DQ is supplied via the input output circuit 16 and the read write amplifier 15 to the memory cell array 11 and is written in memory cells MC specified by these row and column addresses.

The refresh signal IREF is a signal to be activated when the command signals COM indicates a refresh command. The refresh signal IREF is supplied to the refresh control circuit 40. The refresh control circuit 40 is a circuit which activates a predetermined word line WL included in the memory cell array 11 by controlling the row decoder 12 and thereby performs a refresh operation. To the refresh control circuit 40, in addition to the refresh signal IREF, an active signal IACT, an address signal IADD, a reset signal RESET inputted via the reset terminal 22, and further a test active command TACT are supplied. The refresh control circuit 40 includes counting circuits provided so as to correspond to a plurality of word lines WL, and the counting circuits are configured to not only perform control of counting a number of accesses to the word line correspondingly to the active signal IACT but also retain a first value irrespective of the number of accesses to the word lines WL according to the test active signal TACT.

The mode register set signal MRS is a signal to be activated when the command signal COM indicates a mode register set command. Therefore, when not only a mode register set command is inputted but also a mode signal is inputted from the command address terminal 21 in synchronization therewith, the set value of the mode register 14 can be rewritten.

Here, referring back to the description of the external terminals provided to the semiconductor device 10, external clock signals CK and /CK are inputted to the clock terminals 23. The external clock signal CK and the external clock signal /CK are signals complementary to each other, and are both supplied to a clock input circuit 34. The external clock signals CK and /CK inputted to the clock input circuit 4 are supplied to an internal clock generation circuit 35, thereby generating an internal clock signal ICLK. The internal clock signal ICLK is supplied to a timing generator 36, thereby generating various internal clock signals. The various internal clock signals generated by the timing generator 36 are supplied to circuit blocks such as the address latch circuit 32 and the command decode circuit 33 to regulate operation timings of these circuit blocks.

The power supply terminals 25 are terminals to which power supply potentials VDD and VSS are supplied. The power supply potentials VDD and VSS supplied to the power supply terminals 25 are supplied to an internal voltage generation circuit 37. The internal voltage generation circuit 37 generates various internal potentials VPP, VOD, VARY, and VPERI and a reference potential ZQVREF, based on the power supply potentials VDD and VSS. The internal potential VPP is a potential for use in the row decoder 12, the internal potentials VOD and VARY are potentials for use in a sense amplifier in the memory cell array 11, and the internal potential VPERI is a potential for use in many other circuit blocks. On the other hand, the reference potential ZQVREF is a reference potential for use in the calibration circuit 38.

The power supply terminals 26 are terminals to which power supply potentials VDDQ and VSSQ are supplied. The power supply potentials VDDQ and VSSQ supplied to the power supply terminals 26 are supplied to the input output circuit 16. While the power supply potentials VDDQ and VSSQ have the same potential as that of the power supply potentials VDD and VSS supplied to the power supply terminals 25, the dedicated power supply potentials VDDQ and VSSQ are used for the input output circuit 16 so that power supply noise occurring due to the input output circuit 16 do not propagate to other circuit blocks.

The calibration terminal ZQ is connected to the calibration circuit 38. When activated with the calibration signal ZQC, the calibration circuit 38 performs a calibration operation with reference to the impedance of the external resistor RE and the reference potential ZQVREF. An impedance code ZQCODE obtained by the calibration operation is supplied to the input output circuit 16, thereby specifying the impedance of an output buffer (not depicted in the drawing) included in the input output circuit 16.

At the time of an operation test before shipping, the semiconductor device 10 receives an input of a test active signal from the command address terminal 21. Here, the command decode circuit 33 activates the test active signal TACT. The result of the operation test, in more detail, the result of the operation test of the refresh control circuit 40, is outputted to the test output terminal TEST2 as a check signal CHECK. However, the check signal CHECK and the test output terminal TEST2 are not used in a first embodiment, which will be described further below. Together with the test active signal TACT, a count set signal TCOUNT may be supplied from the test input terminal TEST1 to the refresh control circuit 40. Details will be described further below.

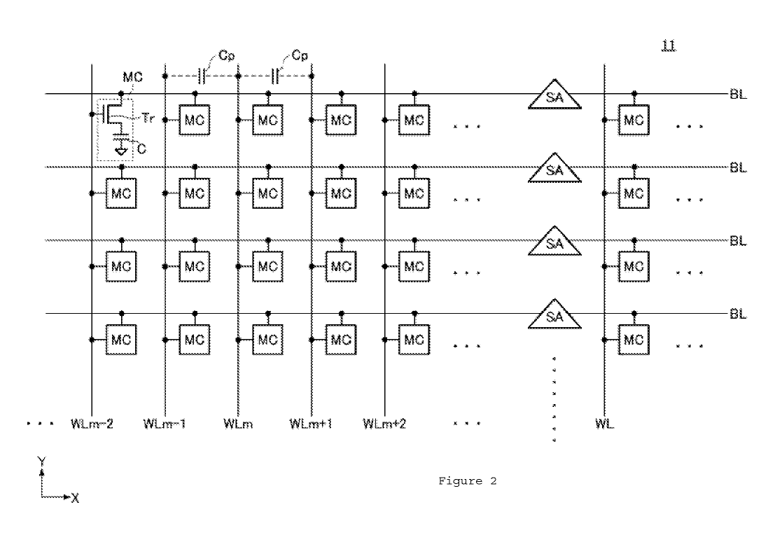

FIG. 2 is a circuit diagram depicting a part of the memory cell array 11 in an enlarged manner.

As depicted in FIG. 2, inside of the memory cell array 11, the plurality of word lines WL extending in a Y direction and the plurality of bit lines BL extending in an X direction are provided, and the memory cells MC are arranged at points of intersection of these lines. The memory cells MC are so-called DRAM cells, each having a structure in which a cell transistor Tr formed of an N-channel-type MOS transistor and a cell capacitor C are connected in series. The gate electrode of the cell transistor Tr is connected to the corresponding word line WL, and one of the source and the drain is connected to the corresponding bit line BL and the other of the source and the drain is connected to the cell capacitor C.

The memory cell MC stores information by electric charges accumulated in the cell capacitor C. Specifically, when the cell capacitor C is charged at the internal potential VARY, that is, when charged at a high level, one logical level (for example, logical value=1) is stored. When the cell capacitor C is charged at the ground potential VSS, that is, when charged at a low level, the other logical level (for example, logical value=0) is stored. Since the electric charges accumulated in the cell capacitor C is gradually lost due to leak current, it is required to perform a refresh operation every time a predetermined time elapses.

The refresh operation is basically identical to row access in response to the active signal IACT. That is, the word line WL to be refreshed is driven at an active level, thereby turning the cell transistor Tr connected to the relevant word line WL ON. The active level of the word line has, for example, the internal potential VPP, which is higher than the internal potential VPERI for use in most of peripheral circuits. With this, the cell capacitor C is connected to the corresponding bit line BL, and therefore the potential of the bit line BL fluctuates according to the electric charges accumulated in the cell capacitor C. Then, with the sense amplifier SA activated, a potential difference between paired bit lines BL is amplified. Since the cell transistor TR is in an ON state, the originally electrically-charged cell capacitor C is recharged by the large potential difference occurring at the bit lines BL. The inactive level of the word line WL has, for example, a negative potential VKK lower than the ground potential VSS.

A cycle in which a refresh operation is to be performed is called a refresh cycle, and is defined as, for example, 64 msec, by standards. Therefore, when the information retaining time of each memory cell MC is designed to be longer than the refresh cycle, information can be continuously retained by a regular refresh operation. Note that, in practice, the information retaining time of each memory cell MC has a margin enough for the refresh cycle and, therefore, even if a refresh operation is performed in a cycle slightly longer than the refresh cycle defined by the standards, the information of the memory cell MC can be accurately retained.

However, a problem of a disturb phenomenon arises in recent years, in which the information retaining time of the memory cell MC is decreased by access history. The disturb phenomenon is a phenomenon in which repeated access to a certain word line WL decreases information retaining margins of the memory cell MC connected to another word line WL adjacent thereto. For example, when a word line WLm depicted in FIG. 2 is repeatedly accessed, information retaining margins of memory cells MC connected to word lines WLm−1 and WLm+1 adjacent thereto. While there are various theories on the cause, for example, a parasitic capacitance Cp occurring between adjacent word lines is thought to be as the cause.

That is, when the predetermined word line WLm is repeatedly accessed, it's potential is repeatedly changed from the negative potential VKK to the high potential VPP. Therefore, although the adjacent word lines WLm−1 and WLm+1 are fixed at the negative potential VKK, their potential is slightly increased by coupling due to the parasitic capacitance Cp. With this, off-leak current of the cell transistors Tr connected to the word lines WLm−1 and the WLm+1 is increased to cause the charge level of the cell capacitor C to be lost quicker than normal.

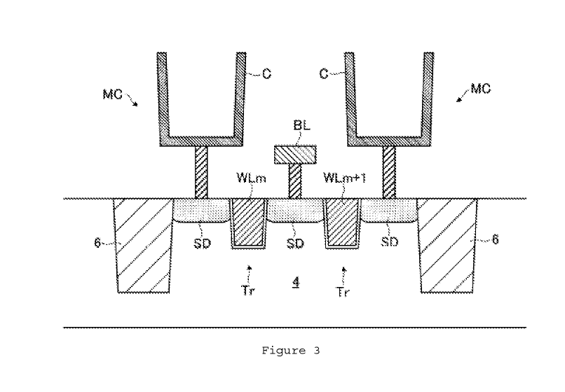

There is another theory as follows. FIG. 3 is a sectional view of two memory cells MC sharing a bit line, each having a trench-gate-type cell transistor Tr with a word line WL buried in a semiconductor substrate 4. Word lines WLm and WLm+1 depicted in FIG. 3 are buried in the same active region sectioned by element isolation regions 6 and, when activated, a channel is formed between corresponding sources/drains SD. One of the source/drain SD is connected to a bit-line node, and the other is connected to a capacitor node. In this cross section, when the word line WLm is accessed and then the cell transistor Tr is turned OFF (that is, when the channel is cut off), floating electrons are accumulated, and these accumulated floating electrons are moved to the capacitor node on a word line WLm+1 side to induce a PN junction leak to cause the charge level of the cell capacitor C to be lost.

In any case, when the information retaining time of the memory cell MC is decreased by the above-described mechanism, there is a danger that the information retaining time may fall short of the refresh cycle defined by the standards. If the information retaining time falls short of the refresh cycle, part of data is lost even if the refresh operation is correctly performed,

In consideration of the above-described disturb phenomenon, various embodiments of the semiconductor device 10 may include a feature of performing an additional refresh operation based on access history. The structure and operation of the refresh control circuit 40 included in the semiconductor device 10 are described in detail below.

### First Embodiment

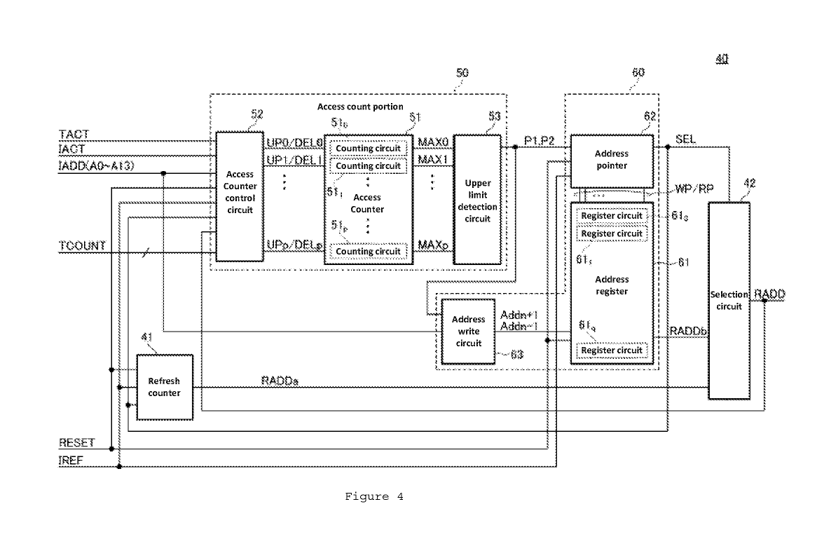

FIG. 4 is a circuit diagram of the refresh control circuit 40 according to the first embodiment.

As depicted in FIG. 4, the refresh control circuit 40 according to the first embodiment includes a refresh counter 41, an access count portion 50, an address generation portion 60, and a selection circuit 42.

The refresh counter 41 is a circuit which generates a row address (refresh address) RADDa to be refreshed in response to a refresh signal IREF. The refresh address RADDa indicating a count value of the circuit is updated (incremented or decremented) in response to the refresh signal IREF. For this reason, if a refresh command is issued a plurality of times (for example, 8 k times) so that the count value of the refresh counter 41 goes around once in a period of one refresh cycle, all word lines WL can be refreshed in the period of one refresh cycle. However, when the select signal SEL is activated, the count value is not updated even if the refresh signal IREF is inputted. Also, when the reset signal RESET is inputted, the count value of the refresh counter 41 is reset to an initial value.

The access count portion 50 is a circuit which analyzes row access history with respect to the memory cell array 11, and includes an access counter 51, an access counter control circuit 52, and an upper limit detection circuit 53. As depicted in FIG. 4, the access counter 51 is configured of counting circuits 51₀ to 51ₚ respectively assigned to the word lines WL0 to WLp, and counting-up or reset of each of the counting circuits 51₀ to 51ₚ is performed by the access counter control circuit 52. Each of the counting circuits 51₀ to 51ₚ is a binary counter including a plurality of flip-flop circuits.

The access counter control circuit 52 receives the active signal IACT, the test active signal TACT, and the address signal IADD, and counts up any of the counting circuits 51₀ to 51ₚ corresponding to the word line WL accessed based on these signals. For example, when the address signal IADD indicating the word line WL0 is inputted with the active signal IACT activated, a count up signal UP0 is activated to count up the counting circuit 51₀ corresponding to the word line WL0.

In the present embodiment, the address signal IADD for row access is configured of fourteen bits of A0 to A13, however, in other embodiments a fewer or greater number of bits may be included in the address signal IADD. Fourteen bits A0 to A13 means that 16 k (=the fourteenth power of 2) word lines WL are included in the memory cell array 11. In this case, 16 k counting circuits are required also in the access counter 51. The number of bits (the number of flip-flop circuits for use) of each of the counting circuits 51₀ to 51ₚ can be any as long as the number is designed according to disturb characteristics and, for example, in some embodiments a sixteen bit counter can be used. In this case, each of the counting circuits 51₀ to 51ₚ can perform counting 64 k (=the sixteenth power of 2) times.

Also, the refresh signal IREF, the refresh address RADD, and the select signal SEL are also supplied to the access counter control circuit 52. The access counter control circuit 52 resets the count value of a predetermined one of the counting circuits 51₀ to 51ₚ based on the refresh signal IREF and the refresh address RADD on condition that the select signal SEL is at a low level. For example, when the select signal SEL is at a low level, upon an input of the refresh address RADD indicating the word line WLm when the refresh signal IREF is activated, a delete signal DELm+1 is activated to reset a counting circuit 51m+1 corresponding to a word line WLm+1. The reason for this will be described further below.

Furthermore, a reset signal RESET is also supplied to the access counter control circuit 52. When the reset signal RESET is inputted, the access counter control circuit 52 activates all of the delete signals DEL0 to DELp, thereby resetting the count values of all of the counting circuits 51₀ to 51ₚ.

With this structure, row access history in response to the active signal IACT is accumulated in the access counter 51. When the count value reaches a predetermined value, each of the counting circuits 51₀ to 51ₚ activates a corresponding one of detection signals MAX0 to MAXp. The detection signals MAX0 to MAXp are supplied to the upper limit detection circuit 53.

When any of the detection signals MAX0 to MAXp is activated, the upper limit detection circuit 53 sequentially activates pointer control signals P1 and P2. The pointer control signals P1 and P2 are supplied to the address generation portion 60.

The address generation portion 60 is a circuit which generates a row address of a word line to be additionally refreshed, and includes an address register 61, an address pointer 62, and an address write circuit 63.

The address register 61 includes a plurality of register circuits 61₀ to 61_{q} each storing a row address of a word line to be additionally refreshed. Any of the register circuits 61₀ to 61_{q} is selected by the address pointer 62, and the row address to be written in the selected one of the register circuits 61₀ to 61_{q} is generated by the address write circuit 63. Also, the reset signal RESET is supplied to the address register 61 and, when activated, the stored contents of all of the register circuits 61₀ to 61_{q} are reset. Note that this reset operation can be omitted.

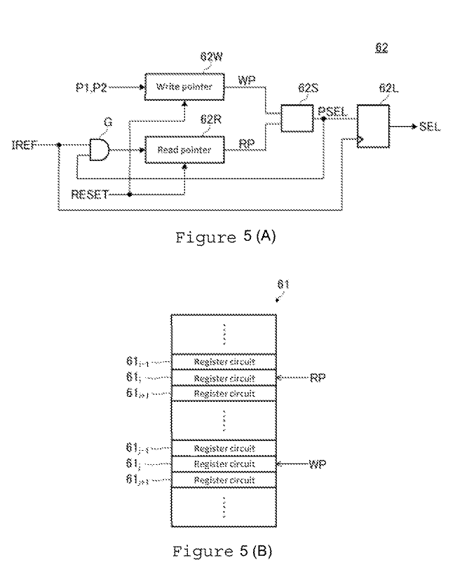

FIG. 5(a) is a circuit diagram of the address pointer 62, and FIG. 5(b) is a schematic diagram for describing a function of the address pointer 62.

As depicted in FIG. 5(a), the address pointer 62 includes a write pointer 62W and a read pointer 62R, a select signal generation circuit 62S, and a latch circuit 62L. The write pointer 62W is a counting circuit which generates a write point signal WP, and the write point signal WP is updated (incremented or decremented) in response to the pointer control signals P1 and P2. As described above, when any of the detection signals MAX0 to MAXp is activated, the upper limit detection circuit 53 sequentially activates the pointer control signals P1 and P2, and therefore the write pointer 62W is updated twice. As depicted in FIG. 5(b), the write point signal WP is used to specify any of the register circuits 61₀ to 61_{q} in which the row address is written. In the example depicted in FIG. 5(b), a register circuit 61ⱼ is specified by the write point signal WP.

The read pointer 62R is a counting circuit which generates a read point signal RP, and the read point signal RP indicating a count value of the circuit is updated (incremented or decremented) in response to an output of an AND gate circuit G. The refresh signal IREF and a select signal PSEL, which will be described further below, are supplied to the AND gate circuit G. Therefore, on condition that the select signal PSEL is activated to a high level, the AND gate circuit G is updated in response to the refresh signal IREF. As depicted in FIG. 5(b), the read point signal RP is used to specify any of the register circuits 61₀ to 61_{q} from which the row address is read. In the example depicted in FIG. 5(b), a register circuit 61, is specified by the read point signal RP. A row address (refresh address) RADDb read from the address register 61 in the above-described manner is supplied to the selection circuit 42.

The select signal generation circuit 62S is a circuit which compares the write point signal WP and the read point signal RP and, when WP>RP, activates the select signal PSEL at a high level. When WP=RP, the select signal PSEL is inactivated to a low level. When the value of the write point signal WP and the value of the read point signal RP match each other, this means that no effective row address is accumulated in the address register 61. The number of row addresses accumulated in the address register 61 is given by a difference (WP−RP) between the value of the write point signal WP and the value of the read point signal RP.

The select signal PSEL is supplied to the latch circuit 62L. The latch circuit 62L latches the select signal PSEL in response to the refresh signal IREF, and outputs the latched signal as the select signal SEL. Therefore, the logical level of the select signal PSEL is reflected to the select signal SEL in response to the next refresh signal IREF.

Also, the reset signal RESET is supplied to the write pointer 62W and the read pointer 62R. When the reset signal RESET is activated, the write point signal WP and the read point signal RP are initialized.

Referring back to FIG. 4, the address signal IADD and the pointer control signals P1 and P2 are supplied to the address write circuit 63. When the pointer control signal P1 is activated, the address write circuit 63 generates a row address (Addn+1) in response to the activation by incrementing the value (Addn) of the address signal IADD, and outputs the row address to the address register 61. Furthermore, when the pointer control signal P2 is activated, the address write circuit 63 generates a row address (Addn−1) in response to the activation by decrementing the value (Addn) of the address signal IADD, and outputs the row address to the address register 61. These row addresses Addn+1 and Addn−1 outputted to the address register 61 are each stored in a different one of the register circuits 61₀ to 61_{q} according to the value of the write point signal WP.

With the above-described structure, the refresh address RADDa is generated by the refresh counter 41, and the refresh address RADDb is generated by the address generation portion 60. These refresh addresses RADDa and RADDb are supplied to the selection circuit 42. Upon receiving these addresses RADDa and RADDb, the selection circuit 42 outputs either one of these addresses to the row decoder 12 as the refresh address RADD. Specifically, the refresh address RADDa is selected when the select signal SEL is inactivated to a low level, and the refresh address RADDb is selected when the select signal SEL is activated to a high level. This means that the refresh address RADDa is selected when an effective row address is not accumulated in the address register 61 and the refresh address RADDb is selected when an effective row address is accumulated in the address register 61.

The test active signal TACT and the count set signal TCOUNT are both for an operation test. The test active signal TACT works as an active signal IACT in the operation test, and the count set signal TCOUNT indicates a count value to be set in the counting circuit (hereinafter referred to as a “test value”). The operation test with the test active signal TACT is (1) to reduce the operation test time and (2) to check the operation of the counting circuits 51₀ to 51ₚ. In the following, three examples of structure for the operation test of the refresh control circuit 40 are described.

### First Structure Example

In a first structure example, only the test active signal TACT is used, and the count set signal TCOUNT is not necessary. To check the operation of the address generation portion 60, any of the detection signals MAX is required to be activated. However, if the setting is such that the detection signal is activated when the count value of the counting circuit reaches a maximum value of 65535, the same word line WL has to be accessed 65535 times. In the operation test, such a large amount of memory accesses in order to check the function of the address generation portion 60 is burdensome.

To avoid such a burden, in the first structure example, when the access counter control circuit 52 receives the test active signal TACT, the count values of the counting circuits 51₀ to 51ₚ included in the access counter 51 are all set at a predetermined test value (a first value). In the case in which the detection signal MAX is activated when the count value of each counting circuit reaches the maximum value of 65535, the test value is set at 65534, and all of the count values of the counting circuits 51₀ to 51ₚ are set at “65534”. After the test value is set, when a word line WLx of the memory cell array 11 is accessed once, a counting circuit 51x corresponding to the word line WLx immediately activates a detection signal MAXx, thereby making it possible to operate the address generation portion 60.

### Second Structure Example

Also in a second structure example, only the test active signal TACT is used, and the count set signal TCOUNT is not necessary. In the second structure example, the access counter control circuit 52 retains the test value in advance. In the second structure example, when the access counter control circuit 52 receives the test active signal TACT, the count value of the counting circuits 51₀ to 51ₚ included in the access counter 51 are all set at the internal test value. Unlike the first structure example, any value can be set to the counting circuits 51₀ to 51ₚ, and therefore it is effective at checking the operation of each of the counting circuits 51₀ to 51ₚ.

### Third Structure Example

In a third structure example, in addition to the test active signal TACT, the count set signal TCOUNT is also used. In the third structure example, when the test active signal TACT is activated, any test value is supplied to the access counter control circuit 52 by using the count set signal TCOUNT. In the third structure example, upon receiving the test active signal TACT, the access counter control circuit 52 sets the count values of all of the counting circuits 51₀ to 51ₚ included in the access counter 51 at the test value indicated by the count set signal TCOUNT. Unlike the first and second structure examples, any test value can be advantageously set from outside even after completion of the semiconductor device 10.

Next, the operation of the semiconductor device 10 using the refresh control circuit 40 according to the present embodiment is described.

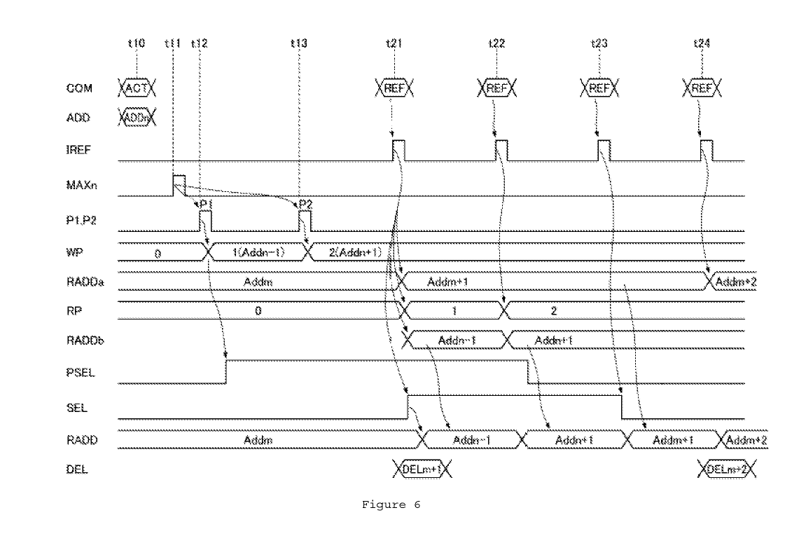

FIG. 6 is a timing diagram for describing the operation of the semiconductor device using the refresh control circuit 40 according to the present embodiment.

In the example depicted in FIG. 6, the case is depicted in which an active command ACT is issued from outside at a time t10 and a refresh command REF is issued from outside at times t21, t22, t23, and t24. Although not depicted, row accesses are performed many times by issuing the active command ACT even before the time t10, and the count value of the counting circuit 51n corresponding to the row address Addn is thereby counted up to a predetermined value−1.

In this state, when the active command ACT and the row address Addn are inputted at the time t10, the count value of the corresponding counting circuit 51n reaches the predetermined value, and therefore the detection signal MAXn is activated to at a time t11. When the detection signal MAXn is activated, the upper limit detection circuit 53 activates the pointer control signals P1 and P2 at times t12 and t13, respectively. In response, the write pointer 62W included in the address pointer 62 updates the write point signal WP indicating the count value at the times t12 and t13. In the example depicted in FIG. 6, the value of the write point signal WP becomes “1” at the time t12, and the value of the write point signal WP becomes “2” at the time t13.

Also, in response to the activation of the pointer control signals P1 and P2, the address write circuit 63 sequentially outputs row address Addn−1 and Addn+1 to the address register 61. With this, the row address Addn−1 is stored in a register circuit 611 included in the address register 61, and the row address Addn+1 is stored in the register circuit 612 included in an address register 612. At this time point, since the value of the read point signal RP is “0”, the select signal PSEL is activated to a high level at the time t11. However, at this time point, the select signal SEL is still at a low level, and therefore the selection circuit 42 selects the refresh address RADDa, which is the output of the refresh counter 41. In the example depicted in FIG. 6, the value of the refresh address RADDa is Addm, and therefore the value of the refresh address RADD outputted from the selection circuit 42 is also Addm.

Next, when the refresh command REF is issued from outside at the time t21, the command decode circuit 33 depicted in FIG. 1 activates the refresh signal IREF. As described above, since the value of the refresh address RADD at this time point is Addm, the row decoder 12 accesses the word line WLm indicated by the row address Addm. With this, information in the memory cell MC connected to the word line WLm is refreshed.

Also, in response to the activation of the refresh signal IREF, the count value of the refresh counter 41 is updated to Addm+1, and the read pointer 62R included in the address pointer 62 updates the value of the read point signal RP indicating a count value of the read pointer to “1”. With this, from the address register 61, the row address Addn−1 stored in the register circuit 611 is outputted.

Furthermore, in response to the activation of the refresh signal IREF, the select signal SEL is changed to a high level, and therefore the selection circuit 42 selects the refresh address RADDb, which is the output of the address register 61. Therefore, the value of the refresh address RADD outputted from the selection circuit 42 becomes Addn−1.

Still further, at the time point when the refresh signal IREF is activated, the select signal SEL is at a low level. Therefore, based on Addm, which is the value of the refresh address RADD, the delete signal DELm+1 is activated to reset the counting circuit 51m+1 corresponding to the word line WLm+1. This is because one reason why the word line WLm is disturbed is a row access to the word line WLm+1 (refer to FIG. 2) and, as a result of the refresh of the word line WLm and reproduction of electric charges, the necessity of preventing a disturb failure of the word line WLm due to counting of row accesses to the word line WLm+1 is eliminated.

However, the row access to the word line WLm+1 causes a disturbance not only to the word line WLm but also to word line WLm+2. Therefore, originally, it is thought that the counting circuit 51m+1 corresponding to the word line WLm+1 should be reset on condition that the word line WLm and the word line WLm+2 are both refreshed. However, when the refresh operation on the word line WLm is in response to the refresh command REF, if the refresh counter 41 is updated twice more, the word line WLm+2 is refreshed. Therefore, it is obvious that the word line WLm+2 is refreshed thereafter in a short period of time. In consideration of this point, in the present embodiment, in response to the refreshment of the word line WLm, the counting circuit 51m+1 corresponding to the word line WLm+1 is reset without waiting for the refresh operation on the word line WLm+2.

As a matter of course, it is also possible to configure the access counter control circuit 52 so that the counting circuit 51m+1 corresponding to the word line WLm+1 is reset on condition that the word line WLm and the word line WLm+2 are both refreshed. In this case, however, the circuit structure of the access counter control circuit 52 is complex a little.

Alternatively, it is possible to reset the counting circuit 51m−1 corresponding to the word line WLm−1 when the refresh on the word line WLm is in response to the refresh command REF. This is because one reason why the word line WLm is disturbed is a row access to the word line WLm−1 and, as a result of the refresh of the word line WLm and reproduction of electric charges, the necessity of preventing a disturb failure of the word line WLm due to counting of row accesses to the word line WLm−1 is eliminated.

Also here, the row access to the word line WLm−1 also causes a disturbance not only to the word line WLm but also to the word line WLm−2. Therefore, originally, it is thought that the counting circuit 51m−1 corresponding to the word line WLm−1 should be reset on condition that the word line WLm and the word line WLm−2 are both refreshed. However, when the refresh operation on the word line WLm is in response to the refresh command REF, the word line WLm−2 is thought to be immediately after the refreshment, and therefore the counting circuit 51m−1 can be rest as described above.

Still further, when the refreshment on the word line WLm is in response to the refresh command REF, it is possible to reset both of the counting circuit 51m−1 corresponding to the word line WLm−1 and the counting circuit 51m+1 corresponding to the word line WLm+1. The reason why this is possible is obvious from the above description, and therefore is not redundantly described herein.

Then, when the refresh command REF is issued again at the time t22, the row decoder 12 accesses the word line WLn−1 indicated by the row address Addn−1. That is, the refresh operation is performed not on the row address Addm+1 indicated by the refresh counter 41 but on the row address Addn−1 indicated by the address register 61 in an interrupting manner. With this, information in the memory cell MC connected to the word line WLn−1 is refreshed. The word line WLn−1 is a word line adjacent to the word line WLn, and has been disturbed by row accesses to the word line WLn over many times. With this, there is a fear of a decrease in information retaining margins of the memory cell MC connected to the word line WLn−1. With the refresh operation on the word line WLn−1 being performed at the time t22 in an interrupting manner, the information can be correctly retained.

Also, since the select signal SEL is at a high level at this time point, even if the refresh signal IREF is activated, the count value of the refresh counter 41 is not updated and is kept at Addm+1. Furthermore, in response to the activation of the refresh signal IREF, the read pointer 62R included in the address pointer 62 updates the value of the read point signal RP indicating the count value of the read pointer to “2”. With this, from the address register 61, the row address Addn+1 stored in the register circuit 612 is outputted. Therefore, the value of the refresh address RADD outputted from the selection circuit 42 is also ADDn+1. Still further, since the value of the read point signal RP matches the value of the write point signal WP, the select signal PSEL is changed to a low level. However, at this time point, the select signal SEL stays at the high level.

When the refresh command REF is further issued at the time t23, the row decoder 12 accesses the word line WLn+1 indicated by the row address Addn+1. That is, the refresh operation is performed on the row address Addn+1 indicated by the address register 61 in an interrupting manner, and the information in the relevant memory cell MC is refreshed. While the word line WLn+1 is also a word line adjacent to the word line WLn and has been disturbed, with the refresh operation being performed on the word line WLn+1 at the time t23 in an interrupting manner, the information can be correctly retained.

Also, with the select signal SEL being at the high level even at this time point, even with the refresh signal IREF being activated, the count value of the refresh counter 41 is not updated and is kept at Addm+1. Furthermore, in response to the activation of the refresh signal IREF, the select signal SEL is changed to a low level. With this, the selection circuit 42 selects the refresh address RADDa outputted from the refresh counter 41. Therefore, the value of the refresh address RADD outputted from the selection circuit 42 is switched to Addm+1.

Then, when the refresh command REF is issued at the time t24, the row decoder 12 accesses the word line WLm+1 indicated by the row address Addm+1. That is, as normally, the refresh operation is performed on the row address indicated by the refresh counter 41. Also, in response to the activation of the refresh signal IREF, the count value of the refresh counter 41 is updated to Addm+2. Furthermore, a delete signal DELm+2 is activated, and a counting circuit 51m+2 corresponding to a word line WLm+2 is reset.

As such, in the present embodiment, when the number of accesses to the word line WLn indicated by the row address Addn reaches a predetermined value, an additional refresh operation is performed on the word lines WLn−1 and WLn+1 adjacent thereto, and the electric charge amount of the memory cells MC decreased due to disturbance is recharged. With this, the information stored in each memory cell MC can be correctly retained irrespectively of access history.

Furthermore, when an additional refresh operation is performed, updating of the count value of the refresh counter 41 is stopped, and therefore a normal refresh operation can be also correctly performed. However, when updating of the count value of the refresh counter 41 is stopped, the number of issuances of the refresh command REF required for the count value of the refresh counter 41 to go round once is increased accordingly. This means that the refresh cycle is slightly prolonged more than a design value. However, as already described above, the information retaining time of each memory cell MC has a margin enough for the refresh cycle in practice. Therefore, even when the refresh operation is performed in a cycle slightly longer than the refresh cycle defined by the standards, the information in the memory cell MC is correctly retained.

### Second Embodiment

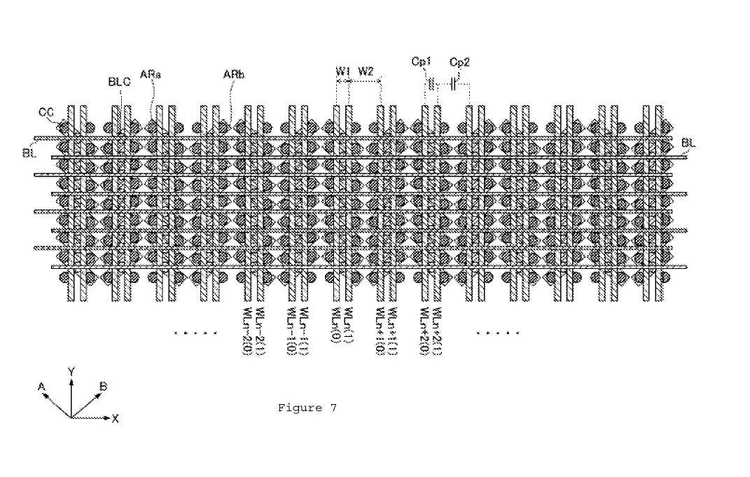

FIG. 7 is a schematic plan view depicting the structure of a memory cell array 11 in the second embodiment of the present invention.

As depicted in FIG. 7, in the present embodiment, word lines WL (for example, word lines WLn(0) and WLn(1)) corresponding to two cell transistors Tr sharing a bit line contact BLC are arranged so as to be adjacent to each other, and a space therebetween is W1. The bit line contact BLC is a contact conductor for connecting one of the source/drain of the cell transistor Tr and a bit line BL. The other of the source/drain is connected via a cell contact CC to a cell capacitor.

By contrast, adjacent word lines WL (for example, word lines WLn(1) and WLn+1(0)) corresponding to cell transistors Tr not sharing any bit line contact BLC have a space W2, which is wider than the space W1. The reason for this layout is that, as depicted in FIG. 7, an active region ARa in an A direction as a longitudinal direction and an active region ARb in a B direction as a longitudinal direction are alternately formed in an X direction.

When the memory cell array 11 has this layout, if a certain word line WLn(0) is repeatedly accessed, a disturb phenomenon occurs to the adjacent word line WLn(1) with the space W1 because of a large parasitic capacitance Cp1, but a disturb phenomenon hardly occurs to the adjacent word line WLn−1(1) with the space W2 because a parasitic capacitance Cp2 is small. Therefore, in the case of this layout, it is required to perform an additional refresh operation on the word line WLn(1) where a disturb phenomenon occurs, but it is not required to perform an additional refresh operation on the other word line WLn−1(1).

Also, the word lines WLn(0) and WLn(1) adjacent to each other with the space W1 are different only in the least significant bit (A0) of the assigned row address, and the values of other bits (A1 to A13) are the same. In consideration of these features, in the present embodiment, the circuit structure of a refresh control circuit 40 is simplified. In the following, the structure and operation of the refresh control circuit 40 in the present embodiment are described in detail.

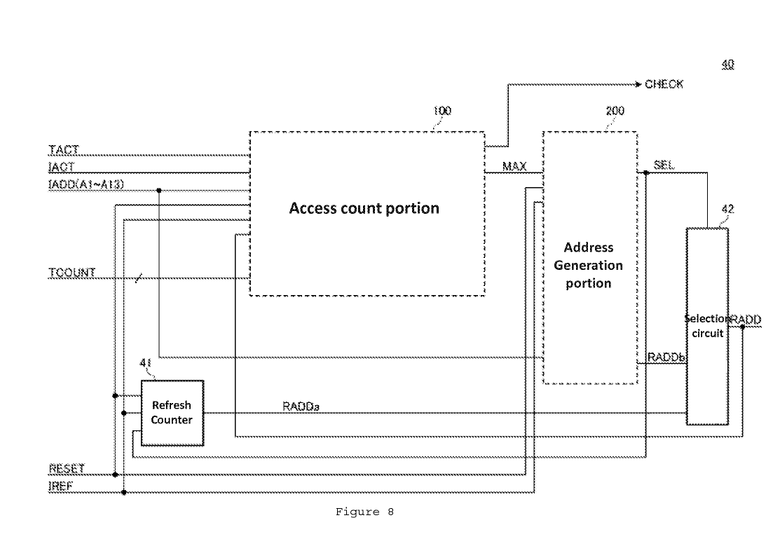

FIG. 8 is a circuit diagram of the refresh control circuit 40 according to an embodiment.

As depicted in FIG. 8, the refresh control circuit 40 according to the second embodiment has a structure approximately similar to that of the refresh control circuit 40 depicted in FIG. 4 except that an access count portion 100 and an address generation portion 200 are used. However, an address signal IADD supplied to the access count portion 100 has only thirteen bits formed of bits A1 to A13 from out of the bits A0 to A13. That is, the least significant bit A0 is degenerated. Also, unlike the first embodiment, a select signal SEL is not fed back to the access count portion 100.

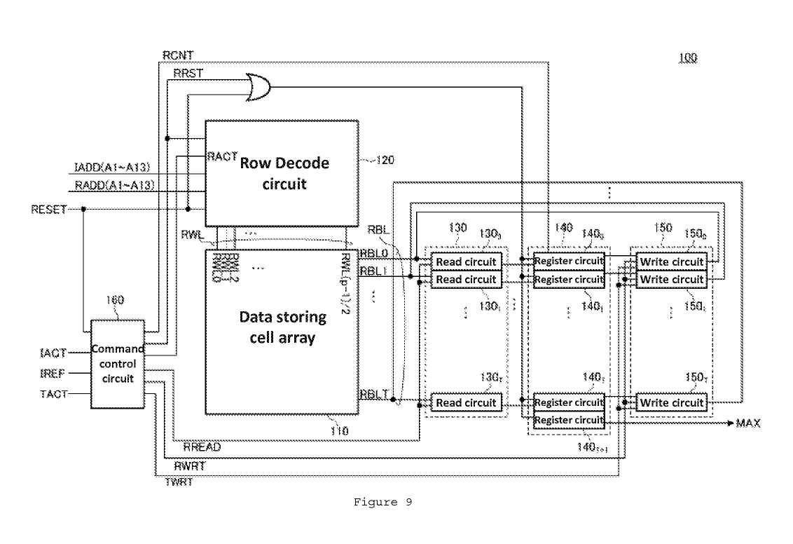

FIG. 9 is a block diagram in a first structure example of the access count portion 100.

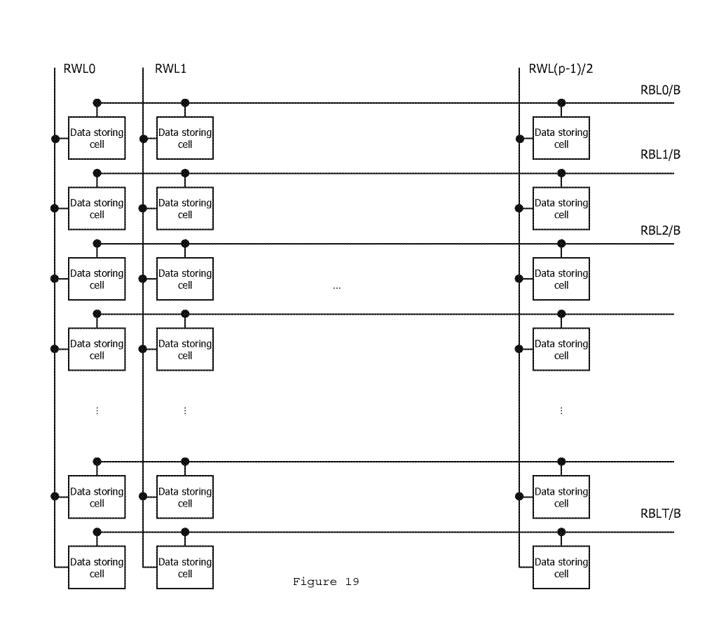

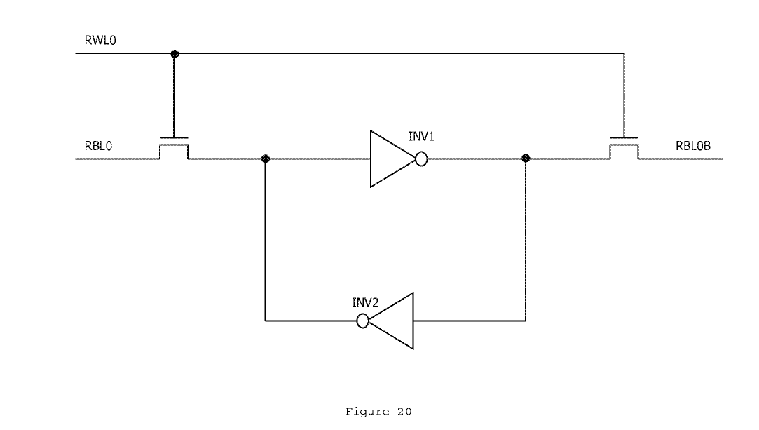

As depicted in FIG. 9, the access count portion 100 has a data storing cell array 110 and a row decoder 120. The counting circuits in FIG. 9 include the data storing cell array 110, a read circuit 130, a register circuit 140, and a write circuit 150. Although not particularly restrictive, the data storing cell array 110 has a structured in which a plurality of data storing cells are arranged in a matrix as depicted in FIG. 19. Here, the plurality of data storing cells forms a group for each row select line RWL. Furthermore, each data storing cell can be configured of, for example, a latch circuit formed of at least two inverter circuits as depicted in FIG. 20. The structure of FIG. 20 is adopted in a so-called SRAM (Static Random Access Memory), in which the output terminal of one inverter circuit is connected to the input terminal of the other inverter circuit and the output terminal of the other inverter circuit is connected to the input terminal of the one inverter circuit. Specifically, the structure has (p+1)/2 word lines RWL0 to RWL(p−1)/2 and T+1 bit lines RBL0 to RBLT, and SRAM cells are arranged at points of intersection of these lines. Here, the value of p+1 represents the number of word lines WL0 to WLp included in the memory cell array 11 depicted in FIG. 1. That is, the number of word lines RWL included in the data storing cell array 110 is a half of the number of word lines WL included in the memory cell array 11. This is because the least significant bit A0 is degenerated in the analysis of access history. Note that while a so-called refresh operation (auto refresh, self refresh) is performed on the memory cells included in the memory cell array 11, such an operation is not required for the data storing cell array 110.

Also, bit lines RBL0 to RBLT are connected to read circuits 130₀ to 130_{T}, respectively, configuring the read circuit 130. The read circuit 130 is a circuit which writes data (count values) read via the bit lines RBL0 to RBLT in register circuits 140₀ to 140_{T} included in the register circuit 140. The register circuits 140₀ to 140_{T} are in a cascade connection, thereby configuring a binary counter. Also, a most significant register circuit 140_{T+1} is added to the register circuits 140, and its value is outputted as a detection signal MAX. Therefore, when the register circuits 140₀ to 140_{T} are counted up as being the maximum value (all 1), the detection signal MAX, which is a value stored in the register circuit 140_{T+1}, is reversed from 0 to 1. As such, the register circuit 140_{T+1} functions as a detection circuit which detects that the count value reaches a predetermined value.

The data (count values) outputted from the register circuits 140₀ to 140_{T} are supplied to the corresponding bit lines RBL0 to RBLT by corresponding write circuits 150₀ to 150_{T}, respectively, and are written back to the relevant data storing cells. Here, the read circuit 130, the register circuit 140, and the write circuit 150 are collectively defined as a count value control circuit.

The operations of these row decoder 120, read circuit 130, register circuit 140, and write circuit 150 are controlled by a command control circuit 160. The command control circuit 160 receives an active signal IACT, a refresh signal IREF, and a reset signal RESET and, based on these signals, generates an active signal RACT, a count up signal RCNT, a reset signal RRST, a read signal RREAD, and a write signal RWRT. Here, the active signal RACT is a signal for activating the row decoder 120, the count up signal RCNT is a signal for counting up the count values of the register circuits 140, and the reset signal RRST is a signal for resetting the count value of the register circuit 140. Also, the read signal RREAD is a signal for activating the read circuit 130, and the write signal RWRT is a signal for activating the write circuit 150.

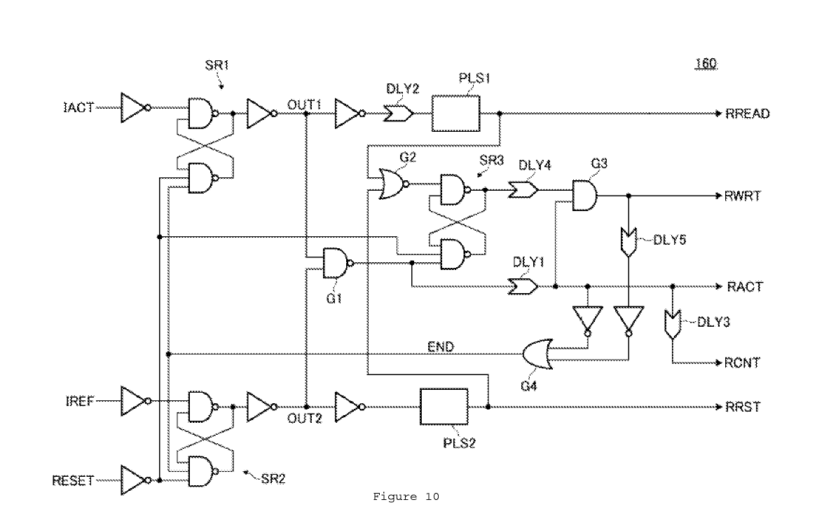

FIG. 10 is a circuit diagram of the command control circuit 160.

As depicted in FIG. 10, the command control circuit 160 includes a latch circuit SR1 set by the active signal IACT and a latch circuit SR2 set by the refresh signal IREF. An output signal OUT1 of the latch circuit SR1 is outputted via a delay element DLY2 and a pulse generation circuit PLS1 as the read signal RREAD. Also, an output signal OUT2 of the latch circuit SR2 is outputted via a pulse generation circuit PLS2 as the reset signal RRST.

Furthermore, the output signals OUT1 and OUT2 are supplied to an NAND gate circuit G1, and an output signal therefrom is outputted via a delay element DLY1 as the active signal RACT. The active signal RACT is outputted via a delay element DLY3 as the count up signal RCNT.

Furthermore, the command control circuit 160 includes a latch circuit SR3 set by an output signal of an NOR gate circuit G2 receiving the read signal RREAD and the reset signal RRST. The latch circuit SR3 is reset by the output signal of the NAND gate circuit G1. An output signal of the latch circuit SR3 is outputted via a delay element DLY4 and the AND gate circuit G3 as the write signal RWRT. The write signal RWRT is fed back to the latch circuits SR1 and SR2 via a delay element DLY5 and an OR gate circuit G4 and resets these circuits. Also, the latch circuits SR1 to SR3 are reset also by the reset signal RESET.

Note that, although not depicted in FIG. 10, with a logic similar to that of generating the write signal RWRT from the active signal IACT, a logic of generating the write signal TWRT from the test active signal TACT is composed. As will be described further below, when the active signal IACT is activated, the active signal RACT, the read signal RREAD, the count up signal RCNT, and the write signal RWRT are sequentially activated. Similarly, when the test active signal TACT is activated, at least the active signal RACT and (not the write signal RWRT but) the write signal TWRT are sequentially activated. The read signal RREAD and the count up signal RCNT may be or may not be generated in a manner similar to that at the time of the input of the active signal IACT.

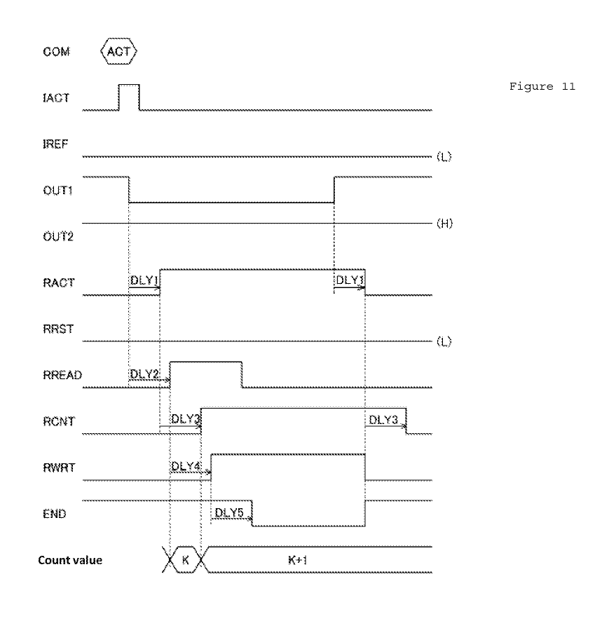

FIG. 11 is a timing diagram for describing the operation of the command control circuit 160 when an active command ACT is issued from outside.

When an active command ACT is issued from outside, the active signal IACT is activated, and the latch circuit SR1 is set. With this active command ACT, a first operation mode is achieved. With this, the output signal OUT1 is changed to a low level, and the active signal RACT and the read signal RREAD are activated in this order. A timing after the output signal OUT1 is changed to a low level until the active signal RACT and the read signal RREAD are activated is defined by the delay amount of the delay elements DLY1 and DLY2. Also, when the active signal RACT is activated, the count up signal RCNT is activated after a delay by the delay element DLY3.

On the other hand, when the read signal RREAD is activated, the latch circuit SR3 is set. Therefore, the write signal RWRT is activated after a delay by the delay element DLY4. Then, an end signal END is activated after a delay by the delay element DLY5, and the latch circuits SR1 and SR3 are reset to be returned to an initial state. In this manner, when the active command ACT is issued from outside, the active signal RACT, the read signal RREAD, the count up signal RCNT, and the write signal RWRT are activated in this order.

First, when the active signal RACT is activated, the row decoder 120 depicted in FIG. 9 selects a word line RWL indicated by the row address IADD (A1 to A13). With this, data (a count value) corresponding to the selected word line RWL is read to a bit line RBL. As described above, in the least significant bit A0 is degenerated in the row address IADD inputted to the access count portion 100. Therefore, the word line RWL selected in response to the active signal RACT is commonly assigned to two word lines WL (for example, a word line WLn(0) and a word line WLn(1)) adjacent to each other with the space W1 depicted in FIG. 7.

Next, when the read signal RREAD is activated, data (a count value) read to the bit line RBL is amplified by the read circuit 130, and is loaded to the register circuit 140. In the example depicted in FIG. 11, the read count value is k, and this value is loaded to the register circuit 140.

Subsequently, when the count up signal RCNT is activated, the count value loaded to the register circuit 140 is incremented. That is, the count value is changed from k to k+1. Then, when the write signal RWRT is activated, the updated count value (k+1) is written back to the data storing cell array 110 via the write circuit 150.

With the above-described operation, the counter value corresponding to the inputted row address IADD (A1 to A13) is incremented. Since this operation is performed every time the active command ACT is issued from outside, the number of row accesses can be counted, with two word lines WL adjacent to each other with the space W1 being taken as a single unit. However, since the least significant bit A0 of the row address IADD is degenerated, the two word lines WL adjacent to each other with the space W1 are not distinguished.

When the value of the most significant register circuit 140T+1 included in the register circuit 140 is reversed from 0 to 1 as a result of repetition of the above-described operation, that is, when the count value reaches a predetermined value, the detection signal MAX is activated to a high level. The detection signal MAX is supplied to the address generation portion 200 depicted in FIG. 8.

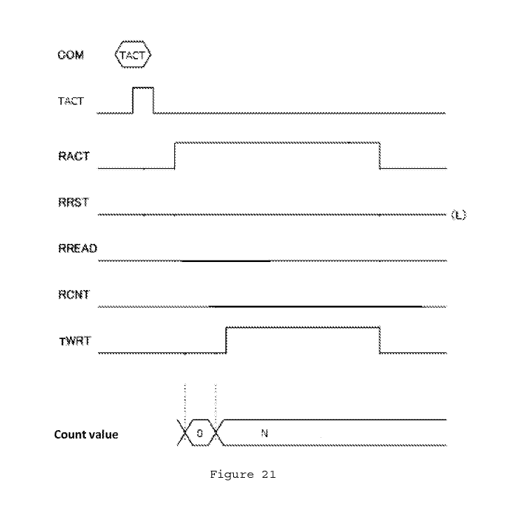

At an operation test, when the test active signal TACT is activated, the command control circuit 160 activates the write signal TWRT in place of the write signal RWRT. With this test active command TACT, a second operation mode is achieved. As depicted in FIG. 21, the write signal tWRT occurring according to the test active command TACT is commonly inputted to the write circuits 150₀ to 150_{T}. When the write signal TWRT is activated, the write circuit 150 writes back a predetermined test value (a first value: N) in the data storing cell array 110 irrespectively of the count value of the register circuit. After the count value of the counting circuit reaches a maximum value (ALL: HIGH), counting up is performed, thereby activating the detection signal MAX. Therefore, if the test value indicating (ALL: HIGH=N indicates a maximum value of the register circuit 140) is set to the register circuit 140 by using the write signal TWRT, a detection signal MAXx can be immediately activated according to the next active command IACT.

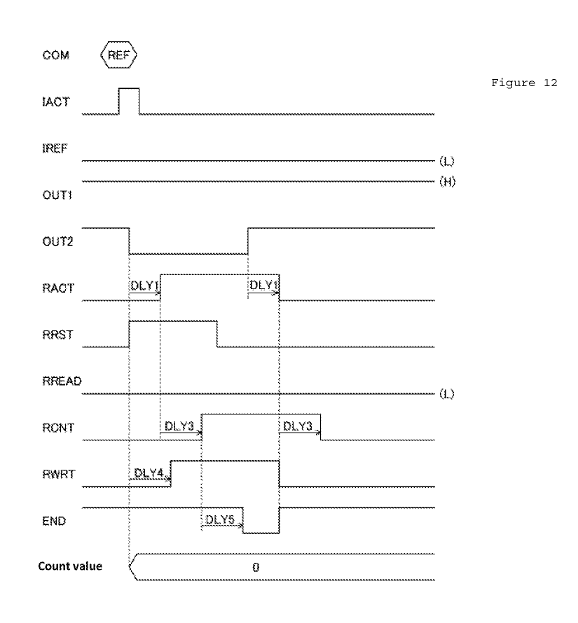

FIG. 12 is a timing diagram for describing the operation of the command control circuit 160 when a refresh command REF is issued from outside.

When the refresh command REF is issued from outside, the refresh signal IREF is activated, and the latch circuit SR2 depicted in FIG. 10 is set. With this, the output signal OUT2 is changed to a low level, and therefore the reset signal RRST and the active signal RACT are activated in this order. A timing after the output signal OUT2 is changed to a low level until the active signal RACT is activated is defined by a delay amount of the delay element DLY1.

When the reset signal RRST is activated, the latch circuit SR3 is set. Therefore, after a delay by the delay element DLY4, the write signal RWRT is activated. Then, after a delay by the delay element DLY5, the end signal END is activated, and the latch circuits SR2 and SR3 are rest to be returned to an initial state. As such, when the refresh command REF is issued from outside, the reset signal RRST, the active signal RACT, and the write signal RWRT signals are activated in this order. While the count up signal RCT is also activated in this example, the operation thereby is ignored by the reset signal RRST. Note that the circuit structure can be such that activation of the count up signal RCNT in response to the refresh command REF is prohibited.

Also, when the reset signal RRST is activated, the register circuits 140₀ to 140_{T} configuring the register circuit 140 are reset. With this, the count value of the register circuit 140 is reset to an initial value (for example, 0). In the present example, the count up signal RCNT is activated thereafter, but the active state of the reset signal RRST is kept, and therefore the count value of the register circuit 140 is kept at the initial value. Next, the active signal RACT is activated, the word line RWL corresponding to the refresh address RADD (A1 to A13) is selected.

Then, when the write signal RWRT is activated, the initialized count value (for example, 0) is written in the data storing cell array 110 via the write circuit 150. With this, the count value corresponding to the relevant word line RWL is initialized to, for example, 0.

With the above-described operation, the count value corresponding to the refresh address RADD (A1 to A13) is initialized. Since the least significant bit A0 of the refresh address RADD is degenerated, when the refresh operation on either of two word lines WL adjacent to each other with the space W1 is performed, the count value common to the two word lines is reset.

The circuit structure and operation of the command control circuit 160 have been described above. With the above-described control by the command control circuit 160, when either of two word lines WL adjacent to each other with the space W1 is accessed, the count value common to the two word lines are counted up, and when the count value reaches a predetermined value, the detection signal is activated. On the other hand, even if either of two word lines WL adjacent to each other with the space W1 is refreshed, the corresponding count value is reset.

Also, when the reset signal RESET is issued from outside, all SRAM cells included in the data storing cell array 110 are reset. With this, all count values are initialized to, for example, 0. This operation is performed by selecting all word lines RWL0 to RWL(p−1)/2 by the row decoder 120 and, in this state, giving an initial value to the bit lines RBL0 to RBLT.

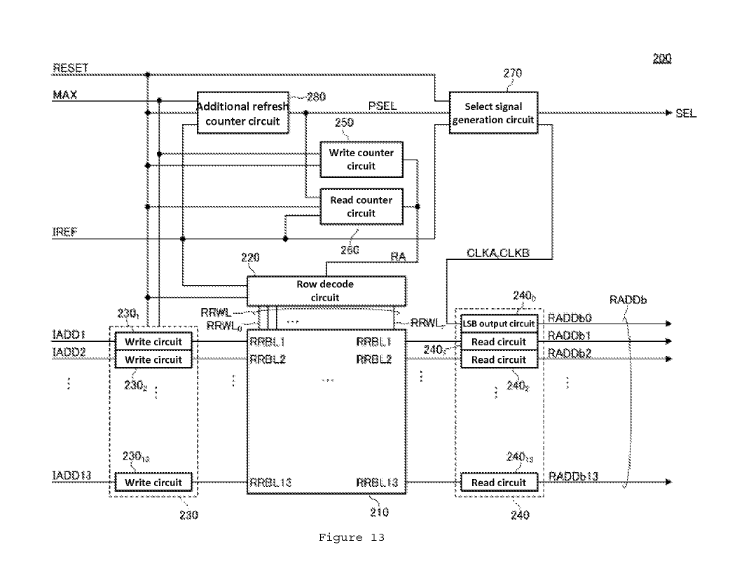

FIG. 13 is a block diagram of the address generation portion 200.

As depicted in FIG. 13, the address generation portion 200 has a memory array 210, a row decoder 220, an address write circuit 230, and an address read circuit 240. Although not particularly restrictive, the memory cell array 210 has a structure in which a plurality of data-retaining latch circuits, for example, a plurality of SRAM (Static Random Access Memory) cells, are arranged in a matrix. Specifically, the memory cell array 210 has a structure having r+1 word lines RRWL0 to RRWLr and thirteen bit lines RRBL1 to RRBL13, with the SRAM cells arranged at points of intersections of these lines.

Any of the word lines RRWL0 to RRWr is selected based on a row address RA outputted from a write counter circuit 250 or a read counter circuit 260 in response to the refresh signal IREF. The row address RA outputted from the write counter circuit 250 is referred to when a row address IADD (A1 to A13) is written in the memory cell array 210 by using the address write circuit 230. The row address RA outputted from the read counter circuit 260 is referred to when a refresh address RADDb (A1 to A13) is read from the memory cell array 210 by using the address write circuit 230. As will be described further below, the row address IADD (A1 to A13) to be written in the memory cell array 210 indicates the word line WLn(0) or WLn(1) the number of accesses to which reaches a predetermined number.

The address write circuit 230 is formed of write circuits 230₁ to 230₁₃ corresponding to respective bits of the row address IADD (A1 to A13), and plays a role of writing the row address IADD (A1 to A13) in the row address RA outputted from the write counter circuit 250.

On the other hand, the address read circuit 240 includes read circuits 240₁ to 240₁₃ corresponding to respective bits of the refresh address RADDb (A1 to A13), and plays a role of reading the refresh address RADDb (A1 to A13) from the row address RA outputted from the read counter circuit 260. Also, the address read circuit 240 includes an LSB output circuit 240₀, and the output signal of the LSB output circuit 240₀ is used as the least significant bit A0 of the refresh address RADDb. The bit A0, which is the output signal of the LSB output circuit 240₀, is reversed based on clock signals CLKA and CLKB outputted from a select signal generation circuit 270.

The select signal generation circuit 270 is a circuit which generates a select signal SEL and the above-described clock signals CLKA and CLKB based on the select signal PSEL and the refresh signal IREF. The select signal SEL is supplied to the selection circuit 42 depicted in FIG. 8 for use in selecting the refresh address RADDa or RADDb, and is also supplied to the refresh counter 41 for use in allowing or prohibiting an updating operation of the refresh counter 41 in response to the refresh signal IREF.

The select signal PSEL is generated by an additional refresh counter 280. The additional refresh counter 280 is a circuit which counts up by two counts in response to the detection signal MAX and counts down by one count in response to the refresh signal IREF, and activates the select signal PSEL when the count value is equal to or larger than 1.

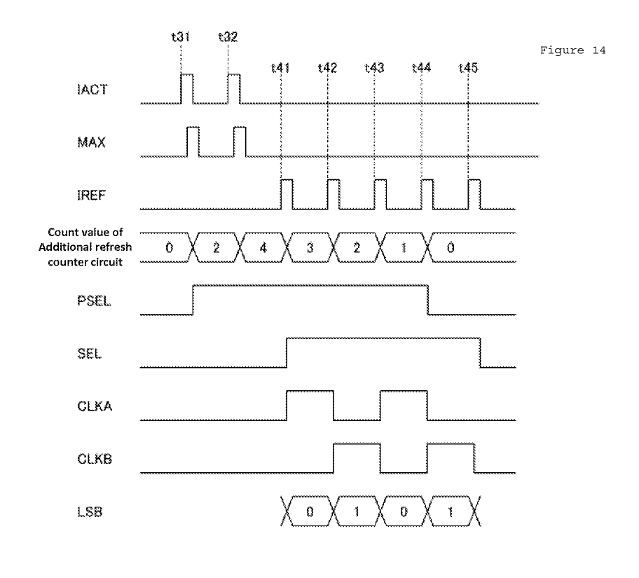

FIG. 14 is a timing diagram for describing the operation of the additional refresh counter 280 and the select signal generation circuit 270.

In the example depicted in FIG. 14, the active signal IACT is activated at times t31 and t32, and the refresh signal IREF is activated at times t41, t42, t43, t44, and t45. Also, in response to the activation of the active signal IACT at the times t31 and t32, the detection signal MAX is activated at both times. This means that, with the row access in response to the active signal IACT at the time t31, the number of accesses to a certain word line WL exceeds a predetermined value and, with the row access in response to the active signal IACT at the time t32, the number of accesses to another word line WL exceeds the predetermined value.

In this case, the count value of the additional refresh counter 280 is counted up from “0” to “2” in response to the first activation of the detection signal MAX, and the count value of the additional refresh counter 280 is counted up from “2” to “4” in response to the second activation of the detection signal MAX. Also, in response to the fact that the count value of the additional refresh counter 280 becomes equal to or larger than “1”, the select signal PSEL is activated to a high level.

Thereafter, in response to the activations of the refresh signal IREF at the times t41, t42, t43, and t44, the count value of the additional refresh counter 280 is counted down to “3”, “2”, “1”, and “0”, and the select signal PSEL is returned to a low level. Note that while the refresh signal IREF is activated also at a time t45, the count value of the additional refresh count 280 is already a minimum value (0), and therefore that value is not changed.

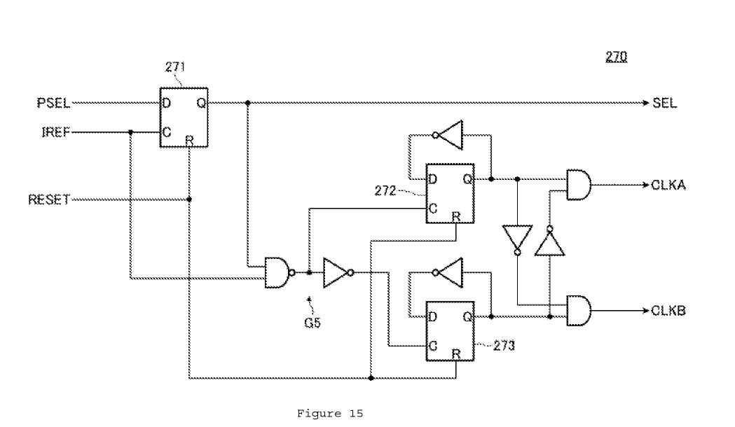

FIG. 15 is a circuit diagram of the select signal generation circuit 270.

As depicted in FIG. 15, the select signal generation circuit 270 includes a latch circuit 271 which latches the select signal PSEL in response to the refresh signal IREF, and an output signal of the latch circuit 271 is used as the select signal PSEL. For this reason, after the select signal PSEL is activated to a high level, the select signal SEL is changed to a high level in response to the next refresh signal IREF (the refresh signal IREF at the time t41 depicted in FIG. 14). Also, after the select signal PSEL is deactivated to a low level, the select signal SEL is returned to a low level in response to the next refresh signal IREF (the refresh signal IREF at the time t45 depicted in FIG. 14).

Furthermore, the select signal and the refresh signal IREF are supplied to a gate circuit G5 depicted in FIG. 15, thereby alternately selecting the latch circuits 272 and 273 based on the refresh signal IREF on condition that the selection signal SEL is activated to a high level. The selected latch circuits 272 and 273 reverse their output signals. Therefore, the clock signals CLKA and CLKB are alternately activated in response to the refresh signal IREF. This means that when the select signal SEL is activated to a high level, the bit A0, which is the output signal of the LSB output circuit 240, is reversed every time the refresh signal IREF is activated.

Still further, as depicted in FIG. 13, the reset signal RESET is supplied to a predetermined circuit block configuring the address generation portion 200 and, when the reset signal is activated, the relevant circuit block is reset to an initial state. For example, data retained in the memory cell array 210 is all reset in response to the reset signal RESET. This operation can be performed, with all word lines RRWL0 to RRWLr selected by the row decoder 220, by outputting an initial value from the address write circuit 230 to the memory cell array 210.

Next, the operation of the semiconductor device 10 using the refresh control circuit 40 according to the present embodiment is described.

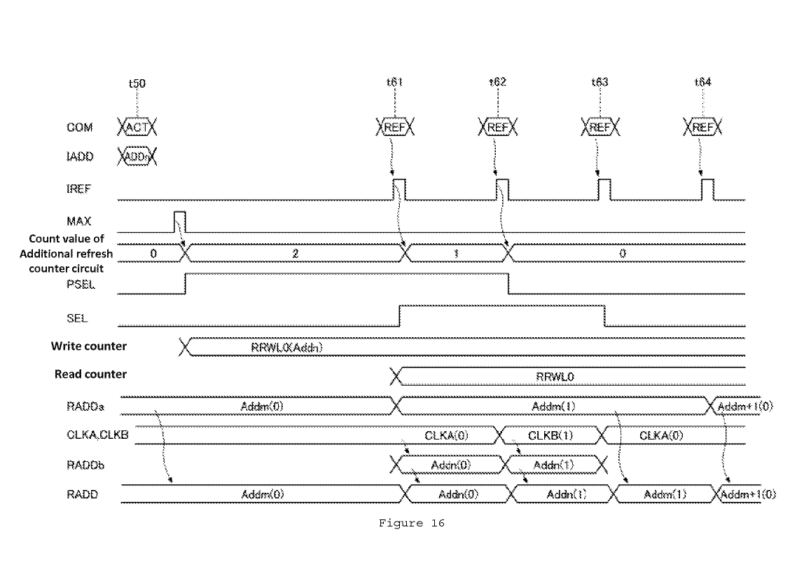

FIG. 16 is a timing diagram for describing the operation of the semiconductor device 10 using the refresh control circuit 40 according to the present embodiment.

In the example depicted in FIG. 16, the case is described in which an active command ACT is issued from outside at a time t50 and a refresh command REF is issued from outside at times t61, t62, t63, and t64. Although not depicted in the drawing, row accesses are performed many times before the time t50 with issuance of the active command ACT. With this, the count value corresponding to the row address Addn of the access count portion 100 is counted up to a predetermined value−1. As described above, since the least significant bit A0 of the row address IADD inputted to the access count portion 100 is degenerated, the row address Addn is common to both of the word line WLn(0) to which the row address Addn(0) is assigned and the word line WLn(1) to which the row address Addn(1) is assigned. Also, before the time t50, the count value of the additional refresh counter 280 is 0.

In this state, when the active command ACT and the row address Addn are inputted at the time t50, the detection signal MAX with a value of the register circuit 140_{T+1} depicted in FIG. 9 is activated. When the detection signal MAX is activated, the count value of the additional refresh counter 280 depicted in FIG. 13 is changed from 0 to 2, and the selection signal PSEL becomes at a high level. Furthermore, since the address write circuit 230 is activated in response to the activation of the detection signal MAX, the row address IADD (Addn) inputted together with the active command ACT is written in the memory cell array 210. A write destination of the row address IADD (Addn) is specified by the write counter 50 as, for example, a word line RRWL0.

However, at this time point, the select signal SEL is still at a low level, and therefore the selection circuit 42 selects the refresh address RADDa, which is the output of the refresh counter 41. In the example depicted in FIG. 16, the value of the refresh address RADDa outputted at this time point is Addm(0), and therefore the value of the refresh address RADD outputted from the selection circuit 42 is also Addm(0). Here, Addm(0) means that the values of the upper bits A1 to A13 are m and the least significant bit A0 is 0.

Next, when the refresh command REF is issued from outside at the time t61, the command decode circuit 33 depicted in FIG. 1 activates the refresh signal IREF. As described above, since the value of the refresh address RADD at this time point is Addm(0), the row decoder 12 accesses the word line WLm indicated by the row address Addm(0). With this, information in the memory cell MC connected to the word line WLm(0) is refreshed.

Also, in response to the activation of the refresh signal IREF, the count value of the refresh counter 41 is updated to Addm(1), and the word line RRWL0 is specified by the read counter circuit 260. Here, Addm(1) means that the values of the upper bits A1 to A13 are m and the value of the least significant bit A0 is 1. With this, from the address read circuit 240, the refresh address RADDb (Addn) stored in the row address corresponding to the word line RRWL0 is outputted. At this time point, since the clock signal CLKA is activated, the value of the LSB output circuit 240₀ is 0, and therefore the value of the refresh address RADDb is Addn(0). Here, Addn(0) means that the values of the upper bits A1 to A13 are n and the value of the least significant bit A0 is 0.

Furthermore, since the select signal SEL is changed to a high level in response to the activation of the refresh signal IREF, the selection circuit 42 selects the refresh address RADDb, which is the output of the address register 61. Therefore, the value of the refresh address RADD outputted from the selection circuit 42 becomes Addn(0). Also, the count value of the additional refresh counter 280 is decremented from 2 to 1.

Still further, with the operation described by using FIG. 12, the count value corresponding to Addm, which is the value of the refresh address RADD, is initialized. The count value corresponding to Addm is a count value common to the word line WLm(0) and the word line WLm(l), but only the least significant bit A0 of the row address is different between these word lines. Therefore, the period from the time when the word line WLm(0) is refreshed to the time when the word line WLm(1) is refreshed is thought to be extremely short. In consideration of this point, irrespectively of which of the word lines WLm(0) and WLm(l) is actually refreshed, once one is refreshed, the count value corresponding to both is reset.

Then, when the refresh command REF is issued again at the time t62, the row decoder 12 accesses the word line WLn(0) indicated by the row address Addn(0), which is the value of the refresh address RADD. That is, a refresh operation is performed not on the row address Addm(1) indicated by the refresh counter 41 but on the row address Addn(0) outputted from the address read circuit 240 in an interrupting manner. With this, information in the memory cell MC connected to the word line WLn(0) is refreshed. Furthermore, with the operation described by using FIG. 12, the count value corresponding to Addn, which is the value of the refresh address, is initialized.

Also, since the select signal SEL is at a high level at this time point, even if the refresh signal IREF is activated, the count value of the refresh counter 41 is not updated is kept at Addm(1). Furthermore, the count value of the additional refresh counter 280 is decremented from 1 to 0. With this, the select signal PSEL is changed to a low level.

Furthermore, in response to the refresh signal IREF, the select signal generation circuit 270 activates the clock signal CLKB. With this, the value of the LSB output circuit 240₀ becomes 1, and the value of the refresh address RADDb is changed to Addn(1). Here, Addn(l) means that the values of the upper bits A1 to A13 are n and the value of the least significant bit A0 is 1.

When the refresh command REF is further issued at the time t63, the row decoder 12 accesses the word line WLn(1) indicated by the row address Addn(1). That is, a refresh operation is performed on the row address Addn(1) outputted from the address read circuit 240 in an interrupting manner, and information in the relevant memory cell MC is refreshed.

Also, since the select signal SEL is at a high level also at this time point, even if the refresh signal IREF is activated, the count value of the refresh counter 41 is not updated and is kept at Addm(1). Furthermore, in response to the activation of the refresh signal IREF, the select signal SEL is changed to a low level. With this, the selection circuit 42 selects the refresh address RADDa outputted from the refresh counter 41, and therefore the value of the refresh address RADD outputted from the selection circuit 42 becomes Addm(1).

Then, when the refresh command REF is issued at the time t64, the row decoder 12 accesses the word line WLm(1) indicated by the row address Addm(1). That is, as normally, a refresh operation is performed on the row address indicated by the refresh counter 41. Also, in response to the activation of the refresh signal IREF, the count value of the refresh counter 41 is updated to Addm+1(0). Furthermore, with the operation described by using FIG. 12, the count value corresponding to Addm+1, which is the value of the refresh address RADD, is initialized.

As such, when a total number of row accesses to the word line WLn(0) and the word line WLn(1) indicated by the row address Addn reaches a predetermined value, an additional refresh operation is performed on these word lines WLn(0) and WLn(1). In the present embodiment, since the least significant bit A0 of the row address IADD is degenerated, irrespectively of either of the word lines WLn(0) and WLn(1) is disturbed, an additional refresh operation is performed on both of these word lines WLn(0) and WLn(1) adjacent to each other with the space W1. For this reason, the capacity of the data storing cell array 110 included in the access count portion 100 can be reduced by half.

Furthermore, since the row address on which counting of the number of accesses and an additional refresh operation are to be performed is retained by using the data storing cell array 110, 210, it is also possible to reduce the occupied area on a chip, compared with the case of using a flip-flop circuit or the like.

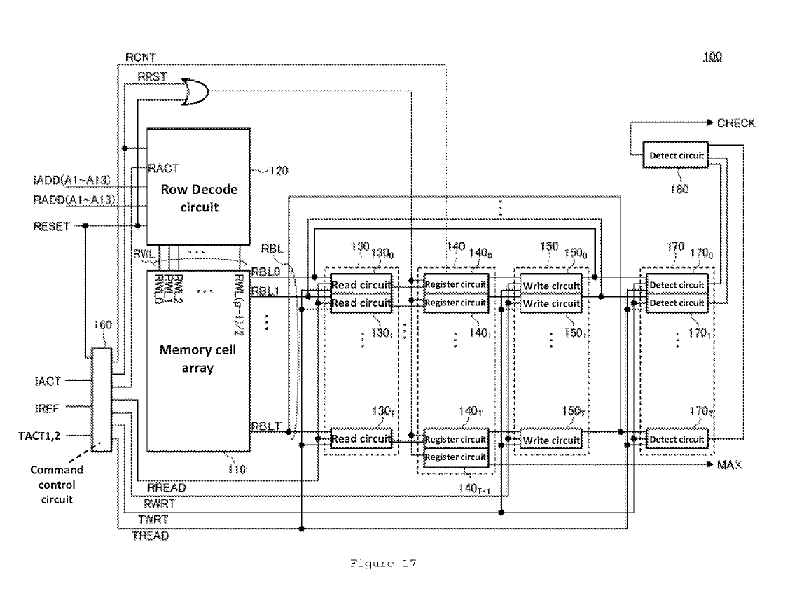

FIG. 17 is a block diagram in an example of the access count portion 100.

In the second structure example, when the test active signal TACT is activated, a write signal TWRT is activated in place of the write signal RWRT, and a read signal TREAD is activated in place of the read signal RREAD. Also, detect circuits 170₀ to 170_{T} are connected to subsequent stages of the write circuits 150₀ to 150_{T}. To each detect circuit 170, the write signal TWRT and the read signal TREAD are inputted, and their outputs are inputted to the detect circuit 180. An output of the detect circuit 180 is a check signal CHECK.

In the second structure example, each write circuit 150 retains a predetermined test value (a first value) in advance. As with the second structure example of the first embodiment, any test value can be retained. When a test active signal TACT1 is activated, in response to the write signal TWRT, the write circuit 150 writes back not the count value outputted from the register circuit 140 but the retained test value to the data storing cell array 110. Also, this test value is outputted to the detect circuit 170, and the detect circuit 170 latches the test value (a second value).

Subsequently, when a test active signal TACT2 is activated, in response to the read signal TREAD this time, the read circuit 130 reads the count value from the memory cell array 110. If the data storing cell array 110 is in a normal state, the test value previously written (the first value) is read as the count value. The read count value is sent via the register circuit and the write circuit to the detect circuit 170. The detect circuit 170 detects whether the count value (test value) previously latched and the count value read from the data storing cell array 110 match each other. If the information retaining function of the data storing cell array 110 is not defective, the test value is written in the data storing cell array 110 by using the test active signal TACT1 at the first time, and the count value actually written in the data storing cell array 110 by using the test active signal TACT2 at the second time and the test value match each other. The detect circuit 170 may be an XOR circuit. When non-match (that is, an information recording error) is detected in any detect circuit 170, the detect circuit 180 inactivates the check signal CHECK to make a notification about a fault of the data storing cell array 110.

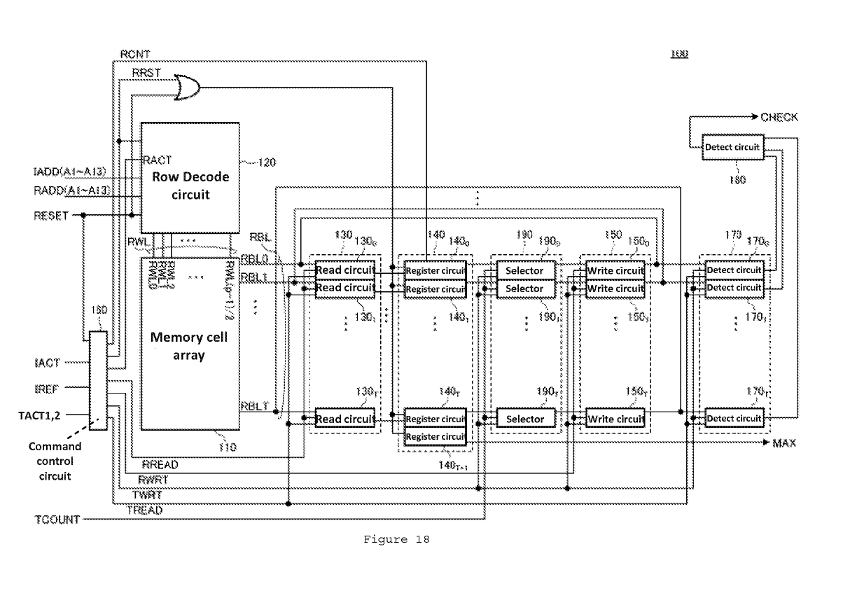

FIG. 18 is a block diagram of an example of the access count portion 100.

In the third structure example, selectors 190₀ to 190_{T} are further connected to the register circuit 140 and the write circuit 150. To each selector 190, the output from the register circuit 140, the write signal TWRT, and the count set signal TCOUNT are inputted, and an output of the selector 190 is inputted to the write circuit 150. The third structure example is identical to the second structure example in that the output of the detect circuit 180 is the check signal CHECK.

In the third structure example, a test value is specified by the count set signal TCOUNT. A basic operation process is identical to that of the second structure example. When the test active signal TACT1 is activated, in response to the write signal TWRT, the selector 190 supplies the test value by using the count set signal TCOUNT to the write circuit 150. The write circuit 150 writes back the test value in the data storing cell array 110, and also outputs the test value to the detect circuit 170, and the detect circuit 170 latches the test value.

Subsequently, when the test active signal TACT2 is activated, in response to the read signal TREAD this time, the read circuit 130 reads the count value from the data storing cell array 110. If the data storing cell array 110 is in a normal state, the test value is read as the count value. The read count value is sent via the register circuit, the selector 190, and the write circuit to the detect circuit 170. The detect circuit 170 detects whether the test value previously latched and the count value read from the data storing cell array 110 match each other. When non-match (that is, an information recording error) is detected in any detect circuit 170, the detect circuit 180 inactivates the check signal CHECK to make a notification about a fault of the data storing cell array 110.

While various embodiments of the present invention have been described above, the present invention is not restricted to the above-described embodiments and can be variously changed in a range not deviating from the gist of the present invention, and it goes without saying that these changes are also included in the scope of the present invention.

What is claimed is:

1. A semiconductor device comprising:
a memory cell array including a plurality of memory cells each configured to be accessed responsive to an input of a corresponding one of row addresses;
a data storing cell array including a plurality of groups of data storing cells each configured to be accessed responsive to the input of the corresponding one of the row addresses; and
a count value control circuit coupled to each of the groups of the data storing cells, the count value control circuit being configured to update a count value stored in each of the groups of data storing cells by a first value responsive to the input of the corresponding one of the row addresses in a first operation mode and to set the count value stored in each of the groups of the data storing cells to a second value responsive to the input of the corresponding one of the row addresses in a second operation mode.

2. The semiconductor device as claimed in claim 1, wherein each of the memory cells includes a capacitor.

3. The semiconductor device as claimed in claim 1, wherein each of the data storing cells includes at least two inverter circuits of which one's output node couples to the other's input node.

4. The semiconductor device as claimed in claim 1, wherein the data storing cell array includes a plurality of row select lines each coupled to a corresponding one of the groups of the data storing cells, each row select line of the plurality of row select lines activated responsive to the input of the corresponding one of the row addresses.

5. The semiconductor device as claimed in claim 1, wherein the count value control circuit includes a plurality of register circuits connected in series to each other and each of the register circuits is coupled to a corresponding one of the data storing cells of each of the groups.

6. The semiconductor device as claimed in claim 5, wherein the register circuits are configured to store data bits read from each of the groups of the data storing cells as the count value and to invert at least one of the data bits stored in the register circuits to update the count value in the first operation mode.

7. The semiconductor device as claimed in claim 5, wherein the count value control circuit further includes a plurality of write circuits each coupled to a corresponding one of the register circuits and the corresponding one of the data storing cells of each of the groups.

8. The semiconductor device as claimed in claim 5, wherein the count value control circuit further includes a plurality of write circuits, each of the write circuits being coupled to a corresponding one of the register circuits to receive updated data bits and the corresponding one of the data storing cells of each of the groups to write each of the updated data bits to the corresponding one of the data storing cells.

9. The semiconductor device as claimed in claim 1, wherein the memory cells are configured such that a refresh operation is performed on the memory cells and the data storing cells are configured such that a refresh operation is not performed on the data storing cells.

10. The semiconductor device as claimed in claim 1, wherein the count value control circuit is configured to output a max signal in each of the first and second operation modes when the count value exceeds a predetermined value.

11. A semiconductor device comprising:
a plurality of data storing cells configured to store a first count value; and
a count value control circuit including a register circuit configured to update the first count value to the second count value responsive to a first control signal and the count value control circuit further including a write circuit coupled between the data storing cells and the register circuit;
the write circuit being configured to write the second count value to the data storing cells responsive to a second control signal and to write a third count value different from each of the first and second count values responsive to a third control signal.

12. The semiconductor device as claimed in claim 11, further comprising a plurality of memory cells and a word line coupled to the memory cells, the first count value representing a number of times the word line is selected.

13. The semiconductor device as claimed in claim 12, wherein the first control signal is activated responsive to the activation of the word line.

14. The semiconductor device as claimed in claim 13, wherein the second control signal is activated responsive to the activation of the word line after an activation of the first control signal.

15. The semiconductor device as claimed in claim 14, wherein the third control signal is activated responsive to the activation of the word line after an activation of the second control signal.

16. The semiconductor device as claimed in claim 12, wherein each of the memory cells includes a capacitor and each of the data storing cells includes at least two inverter circuits of which one's output node couples to the other's input node.

17. The semiconductor device as claimed in claim 11, wherein each of the data storing cells includes at least two inverter circuits of which one's output node couples to the other's input node.

18. A semiconductor device comprising:
a memory cell array including a plurality of memory cells that are arranged in a matrix including a plurality of rows and columns, each of the rows being assigned to an individual address of row addresses;
an access circuit configured to access each of the rows responsive to an associated individual address of the row addresses; and
a plurality of counting circuits each provided for an associated one of the rows, each of the counting circuits being configured to count a number of accesses that are performed on an associated one of the rows by the access circuit, each of the counting circuits being further configured to be loaded with a first value that is free from the number of accesses.

19. The device as claimed in claim 18, wherein each of the counting circuits comprises a plurality of data storage cells each different from each of the memory cells.

20. The device as claimed in claim 19, wherein each of the memory cells comprises a DRAM cell and each of the data storage cells comprises an SRAM cell.
